(19) United States
(12) Patent Application Publication
(10) Pub. No.: US 2015/0364445 A1
(43) Pub. Date: Dec. 17, 2015

(54) STACK MODULE PACKAGE AND METHOD FOR MANUFACTURING THE SAME

(71) Applicant: Electronics and Telecommunications Research Institute, Daejeon (KR)

(72) Inventors: Kwang Seong CHOI, Daejeon (KR); Hyun Cheol BAE, Daejeon (KR); Yong Sung EOM, Daejeon (KR); Haksun LEE, Daejeon (KR)

(21) Appl. No.: 14/685,400

(22) Filed: Apr. 13, 2015

(30) Foreign Application Priority Data
Jun. 16, 2014 (KR) 10-2014-0072908

(51) Int. Cl. H01L 25/065; H01L 23/66; H01L 23/367; H01L 23/498

(52) U.S. Cl. CPC H01L 25/0652; H01L 23/49827; H01L 23/49838; H01L 23/66; H01L 23/3675; H01L 2223/6616; H01L 2225/06548; H01L 2225/0651; H01L 2225/06589

(57) ABSTRACT

Provided is a stack module package including: a first substrate where a first device is mounted, and a second substrate where a second device is mounted. The second substrate has a greater thickness than the first substrate, and the second device has a greater thickness than the first device. The first and second devices are vertically connected to each other. In the stack module package, vertical signal loss between the first and second substrates having different characteristics may be minimized

### CROSS-REFERENCE TO RELATED APPLICATIONS

This U.S. non-provisional patent application claims priority under 35 U.S.C. §119 of Korean Patent Application No. 10-2014-0072908, filed on Jun. 16, 2014, the entire contents of which are hereby incorporated by reference.

### BACKGROUND OF THE INVENTION

The present invention disclosed herein relates to a stack module package, and more particularly, to a stack module package and a method for manufacturing the same.

In various industries, demands on high performance and multi functional small, light and thin module packages are increasing continuously. The module packages are variously applied to servers, game consoles, network servers, optical communication modules, radar modules, and lighting components in addition to personal smartphones. In order to meet these market needs, 3D stack packaging techniques are suggested. The 3D package techniques may include a 3D IC technique for three-dimensionally stacking semiconductor chips on the basis of through silicon via (TSV). Alternatively, there is a 2.5D IC technique for mounting or three-dimensionally stacking several semiconductor chips on a silicon interposer substrate including the TSV. Through such a technique, in the case of an RF chip, by three-dimensionally stacking transmitters and receivers or three-dimensionally stacking RF chips and digital chips, a technology for reducing the size of a system and signal loss at the same time, and saving power and increasing an operating frequency is being developed. In the case of a digital field, techniques for three-dimensionally stacking memories, stacking processors and memories, or stacking processors and memories on an interposer substrate in an 2.5D IC form are under development.

### SUMMARY OF THE INVENTION

The present invention provides a stack module package capable of minimizing vertical signal loss between substrates having different characteristics.

The present invention also provides a method for manufacturing a stack module package capable of minimizing signal loss.

Embodiments of the present invention provide stack module packages including: a first substrate where a first device is mounted; first vias penetrating the first substrate; a second substrate where a second device is mounted, the second substrate having a greater thickness than the first substrate and the second device having a greater thickness than the first device; second vias penetrating the second substrate, a first signal pattern and a first ground pattern formed on the first substrate, each being connected to the first device; and a second signal pattern and a second ground pattern formed on the second substrate, each being connected to at least one of the second vias and the second device, wherein the first device and the second device are vertically connected to each other by at least one of the first vias and at least one of the second vias; and the first signal pattern or the first ground pattern is connected to a plurality of the first vias.

In some embodiments, the stack module packages may further include connection parts connecting the first vias and the second vias, and each of the second vias may have a greater diameter than each of the first vias.

In other embodiments, at least two first vias may be connected to the first signal pattern in correspondence to one second via connected to the second signal pattern.

In still other embodiments, the stack module packages may further include: a third substrate interposed between the first substrate and the second substrate, the third substrate provided in a space between a bottom surface of the first substrate and a top surface of the second substrate; and third vias penetrating the third substrate and connecting the first vias and the second vias, wherein the second substrate may have a greater thickness than the third substrate; and each of the second vias may have a greater diameter than each of the third vias.

In even other embodiments, the first signal pattern may be connected to a first bundle including a plurality of first vias; the first ground pattern may surround the first signal pattern to form a closed curve and may be connected to a second bundle including a plurality of first vias; and a protective layer may be interposed between the first signal pattern and the first ground pattern.

In yet other embodiments, a high frequency signal or a high-speed electrical signal may be delivered to the first signal pattern, the first ground pattern, the second signal pattern, and the second ground pattern.

In further embodiments, the second substrate may include a cavity recessed toward a bottom thereof, and wherein the second device may be disposed in the cavity.

In still further embodiments, the stack module packages may further include: a third substrate interposed between the first substrate and the second substrate, the third substrate having a greater thickness than the first substrate, and the third substrate provided in a space between a bottom surface of the first substrate and a top surface of the second substrate; and third vias penetrating the third substrate and connecting the first vias and the second vias, wherein each of the third vias may have a greater diameter than each of the firsts vias; and a level of a top surface of the second device may be disposed between a top surface and a bottom surface of the third substrate.

In even further embodiments, the stack module packages may further include: a fourth substrate disposed below the second substrate and horizontally connected to a third device; and a thermal dissipation plate disposed below the fourth substrate and dissipating a heat generated from the third device.

In yet further embodiments, the third device may consume a higher power than the first device.

In yet further embodiments, the second substrate may have a lower thermal conductivity than the first substrate.

In yet further embodiments, the stack module packages may further include: a fifth substrate where the second device disposed on a top surface thereof and disposed below the second substrate; and fifth vias penetrating the fifth substrate and connected to the second vias, wherein the second substrate may be horizontally connected to the second device and provides a space between a bottom surface of the first substrate and a top surface of the fifth substrate; the second substrate may have a greater thickness than the fifth substrate; and each of the second vias may have a greater diameter than each of the fifth vias.

In yet further embodiments, the stack module packages may further include a fifth signal pattern and a fifth ground pattern formed on the fifth substrate, each being connected to at least one of the fifth vias and connected to the second device, wherein the fifth signal pattern may be connected to a plurality of fifth vias.

In other embodiments of the present invention, stack module packages includes: a first substrate including first vias penetrating an inside thereof; a first conductive pattern formed on the first substrate and connected to at least one of the first vias; a second substrate including second vias penetrating an inside thereof; and a second conductive pattern formed on the second substrate and connected to at least one of the second vias, wherein the second substrate may have a greater thickness than the first substrate; the first conductive pattern and the second conductive pattern may be vertically connected to each other by at least one of the first vias and at least one of the second vias; and the first conductive pattern may be connected to a plurality of first vias.

In some embodiments, each of the second vias may have a greater diameter than each of the first vias.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1A is a circuit diagram of a two-dimensionally arranged RF module according to an embodiment of the present invention.

FIG. 1B is a sectional view of an RF module package taken along a line A-A′ of FIG. 1A.

FIG. 1C is a sectional view when a housing is attached to a module package of FIG. 1B.

FIG. 2A is a plan view of a first substrate where a first device is mounted according to an embodiment of the present invention.

FIG. 2B is a plan view of a second substrate where a second device is mounted according to an embodiment of the present invention.

FIG. 3A is a plan view of a first substrate where a first device is mounted according to an embodiment of the present invention.

FIG. 3B is a plan view of a second substrate where a second device is mounted according to an embodiment of the present invention.

FIG. 3C is a plan view of a stack module package according to an embodiment of the present invention.

FIG. 3D is a sectional view taken along a line A-A′ of FIG. 3C;

FIG. 4A is a sectional view of a stack module package according to an embodiment 1 of the present invention;

FIG. 4B is an enlarged sectional view of an area Y in FIG. 4A;

FIG. 4C is an enlarged sectional view of an area X in FIG. 4A;

FIG. 4D is an enlarged sectional view of an area Z in FIG. 4A;

FIG. 4E is a plan view taken along a line B-B′ of FIG. 4D;

FIGS. 5A to 5E are sectional views illustrating processes for sequentially manufacturing the stack module package according to an embodiment 1 of the present invention;

FIG. 6 is a sectional view of a stack module package according to an embodiment 2 of the present invention; and

FIG. 7 is a sectional view of a stack module package according to an embodiment 3 of the present invention.

### DETAILED DESCRIPTION OF PREFERRED EMBODIMENTS

In order to understand the configuration and effect of the present invention, preferred embodiments of the present invention are described with reference to the accompanying drawings. However, the present invention is not limited to embodiments set forth herein and may be implemented in various forms and with various modifications. Rather, these embodiments are provided so that this disclosure will be thorough and complete, and will fully convey the scope of the present invention to those skilled in the art.

In the specification, it will be understood that when one element is referred to as being ‘on’ another element, it can be directly on the other element, or intervening elements may also be present. In the figures, moreover, the dimensions of elements are exaggerated for clarity of illustration. Like reference numerals refer to like elements throughout. Like reference numerals refer to like elements throughout the specification.

Additionally, the embodiment in the detailed description will be described with sectional and/or plan views as ideal exemplary views of the present invention. Also, in the figures, the dimensions of layers and regions are exaggerated for clarity of illustration. Areas exemplified in the drawings have general properties, and are used to illustrate a specific shape of a semiconductor package region. Thus, this should not be construed as limited to the scope of the present invention. Also, though terms like a first and a second are used to describe various members, components, regions, layers, and/or portions in various embodiments of the present invention, the members, components, regions, layers, and/or portions are not limited to these terms. These terms are used only to discriminate one region or layer from another region or layer. An embodiment described and exemplified herein includes a complementary embodiment thereof.

In the following description, the technical terms are used only for explaining specific embodiments while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

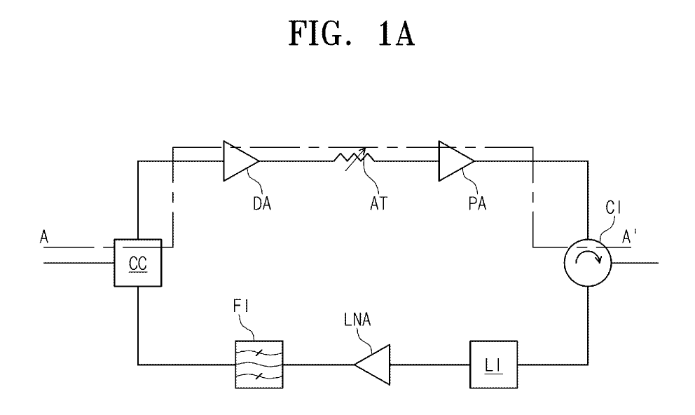

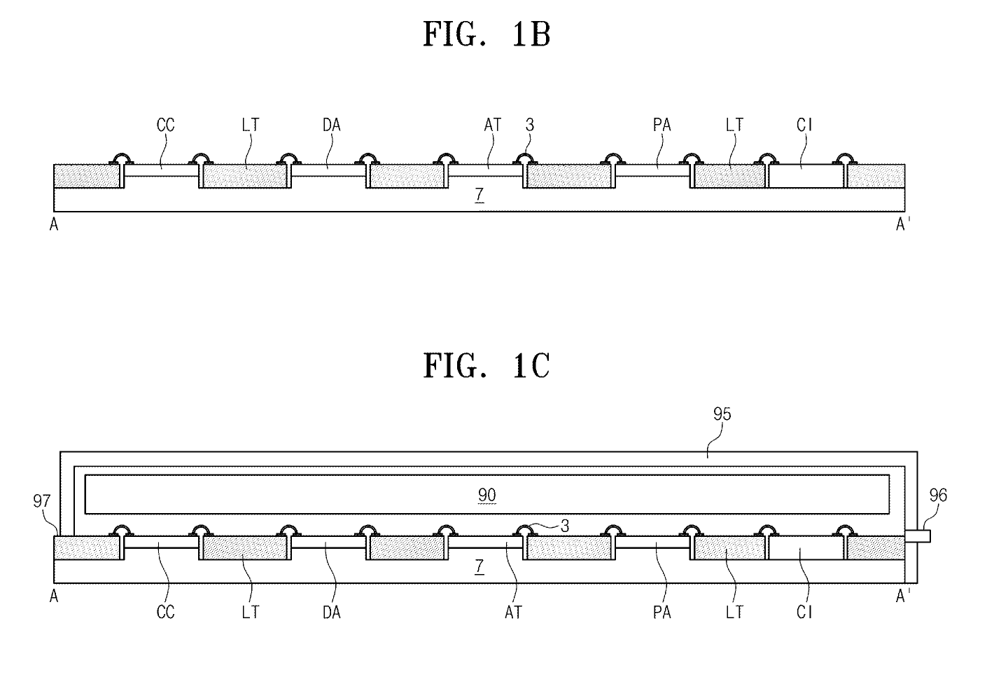

FIG. 1A is a circuit diagram of a two-dimensionally arranged RF module according to an embodiment of the present invention. Referring to FIG. 1A, a circuit diagram of an RF module may include a plurality of devices and in more detail, may include a core chip CC, a driving amplifier DA, an attenuator AT, a power amplifier PA, a circulator CI, a limiter LI, a low noise amplifier LNA, and a filter FI. The circulator CI may be connected to an external antenna and the core chip CC may input/output high frequency signals.

FIG. 1B is a sectional view of an RF module package taken along a line A-A′ of FIG. 1A. Referring to FIG. 1B, The RF module may include a plurality of devices along the line A-A′ of the circuit diagram of the RF module and in more detail, may include a core chip CC, a driving amplifier DA, an attenuator AT, a power amplifier PA, and a circulator CI. The plurality of devices may be disposed on a heat dissipation plate 7. In more detail, the plurality of devices may be die-bonded to the heat dissipation plate 7 and also may contact the heat dissipation plate 7 directly. Furthermore, the RF module package may be disposed on the heat dissipation plate 7 and may include a plurality of substrates LT for connecting the devices to each other. Each of the plurality of substrates LT may be disposed between the device and its adjacent device adjacent thereto and may be horizontally connected to the device and its adjacent device through a wire 3. Although not shown in the drawing, each of the plurality of substrates LT includes a rewiring layer thereon, thereby connecting the devices to each other. The substrate may be a Low Temperature Co-fired Ceramic (LTCC) substrate.

In the case of the power amplifier PA among the plurality of devices, it can consume tens to hundreds of W. Accordingly, in this case, it is necessary to transfer the heat generated from the power amplifier PA to the outside efficiently. At this point, the heat dissipation plate 7 may efficiently discharge the heat generated from the power amplifier PA to the outside by directly contacting the power amplifier PA. Furthermore, the heat dissipation plate 7 may efficiently discharge the heat generated from the remaining devices in addition to the power amplifier PA to the outside.

Moreover, the circulator CI among the plurality of devices may have a greater thickness and a greater width, compared to other devices. In more detail, general devices the RF module package may have a thickness of about 100 μm. On the other hand, the circulator CI may have a thickness of several mm.

FIG. 1C is a sectional view when a housing 95 is attached to a module package of FIG. 1B. Referring to FIG. 1C, the driving module 90 may be disposed on the plurality of devices. Although not shown in the drawing, the driving module 90 and the plurality of devices may be electrically connected to each other. The RF module package where the driving module 90 is disposed may be sealed by the metal housing 95. Although not shown in the drawing, one end of the RF module package may be connected to a surface mount RF port 97, so that a high frequency signal may be inputted to or outputted from the core chip CC. The other side one end of the RF module package may be connected to the RF connector 96 and the circulator CI may be connected to an external antenna through the RF connector 96.

As described above, referring to FIGS. 1A to 1C, an example of a two-dimensionally arranged RF module package is described. Moreover, when such an RF module package is three-dimensionally provided, the size of a module is reduced and thus the weight and volume can be greatly reduced. Due to this, the economic efficiency of the module can be improved. Additionally, the characteristics of the module can be improved. Moreover, when the LTCC substrate is used to implement a three-dimensionally arranged RF module package, several issues may arise. In more detail, in the case of the LTCC, the minimum line width is about 100 μm and the diameter of a via penetrating the LTCC substrate is more than about 100 μm, so that it is difficult to implement an RF circuit small. Additionally, since the thermal conductivity value of the LTCC substrate is about 2 W/m·K to about 3 W/m·K, it is difficult to dissipate the heat generated from a plurality of devices.

In order to solve such issues, a silicon interposer substrate including Though Silicon Via (TSV) instead of an LTCC substrate may be used. In general, the diameter of a TSV is as small as several μm to tens μm and the thickness of the silicon interposer substrate is also as thin as tens μm to hundreds μm. Additionally, the line width of a rewiring layer formed on the silicon interposer substrate may be as thin as several μm to tens μm. That is, since the silicon interposer substrate is very small compared to the LTCC substrate, it may be useful in reducing the size of a module package. Furthermore, the thermal conductivity value of the silicon interposer substrate is as large as about 150 W/m·K, it may serve as heat dissipation plate by itself.

In order to implement a three-dimensionally arranged RF module package by using the above-mentioned silicon interposer substrate, the thicknesses of all devices need to be smaller than that of the silicon interposer substrate. However, as described above, in the case of the circulator CI among the plurality of devices, its thickness may is several mm, that is, may have a greater thickness than the silicon interposer substrate. Accordingly, since the circulator CI is directly mounted on the silicon interposer substrate, it is difficult to arrange it three-dimensionally together with other devices. In order to directly mount the circulator CI on the silicon interposer substrate, it is necessary to increase the thickness of the silicon interposer substrate to several mm and also increase the thickness of the diameter of the TSV to several mm. However, this would be difficult with current technology.

The purpose of the present invention is to provide a three-dimensionally arranged stack module package. Especially, as described above, when devices in a package have different thicknesses, the present invention may provide a structure for connecting them three-dimensionally. Furthermore, provided is a stack module package for minimizing electrical and/or frequency signal loss between the devices.

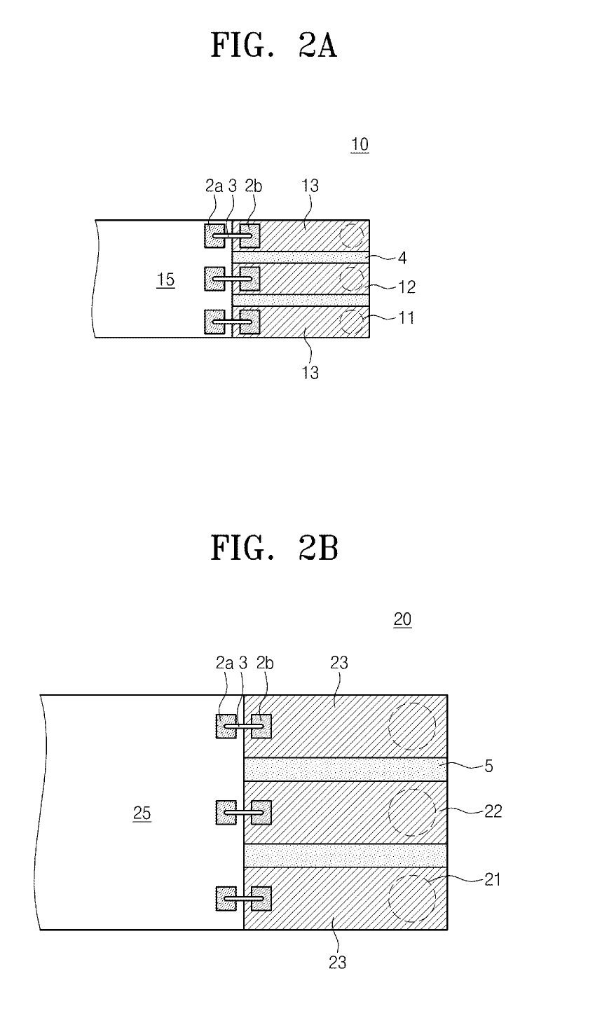

FIG. 2A is a plan view of a first substrate 10 where a first device 15 is mounted according to an embodiment of the present invention. FIG. 2B is a plan view of a second substrate 20 where a second device 25 is mounted according to an embodiment of the present invention. Referring to FIGS. 2A and 2B, provided are the first substrate 10 where the first device 15 is mounted and the second substrate 20 where the second device 25 having a greater thickness than the first device 15 is mounted. The second substrate 20 may have a greater thickness than the first substrate 10 in order to mount the second device 25.

The substrate 10 having the first device 15 mounted thereon will be described in more detail. A protective layer 4 may be disposed on the first substrate 10 and furthermore, first conductive patterns 12 and 13 may be formed on the first substrate 10. The first conductive patterns 12 and 13 may include at least one first signal pattern 12 and at least one first ground pattern 13. The first signal patterns 12 and the first ground patterns 13 may be exposed to the outside. Device connection terminals 2a may be disposed on the first device 15 and substrate connection terminals 2b may be disposed on each of the first signal patterns 12 and the first ground patterns 13. The device connection terminals 2a and the substrate connection terminals 2b may be connected to each other through a wire 3, so that the first device 15 may be connected to the first signal patterns 12 and the first ground patterns 13. Each of the first signal patterns 12 and the first ground patterns 13 may be connected to a first via 11 penetrating the first substrate 10. The substrate 10 may be a silicon interposer substrate.

The second substrate 20 having the second device 25 mounted thereon may be identical to the first substrate 10 having the first device 15 mounted thereon. However, an insulation layer 5 may be disposed on the second substrate 20. Additionally, in relation to the second substrate 20, the width of each of the second conductive patterns 22 and 23 formed on the second substrate 20 may be greater than the width of each of the first conductive patterns 12 and 13. In more detail, the width of each of the second signal patterns 22 and the second ground patterns 23 may be greater than the width of each of the first signal patterns 12 and the first ground patterns 13. Additionally, each of the second vias 21 connected to the second signal patterns 22 and the second ground patterns 23 may have a greater diameter than each of the first vias 11. The second substrate 20 may be a ceramic substrate such as an LTCC substrate or a plastic substrate such as a PCB substrate.

In order to implement a three-dimensionally arranged stack module package, the first substrate 10 having the first device 15 mounted thereon needs to be vertically connected to the second substrate 20 having the second device mounted thereon. However, since the second substrate 20 has a greater scale than the first substrate 10, it is difficult to connect them vertically. In more detail, since the signal and ground pattern width of the second substrate 20 are greater than those of the first substrate 10 and the via diameter of the second substrate 20 is greater than that of the first substrate 10, it is difficult to connect them vertically in terms of physical structure. Additionally, in transmitting electrical and/or high frequency signals three-dimensionally, signal loss may occur greatly between the first substrate 10 and the second substrate 20 having different characteristics. Furthermore, when the first substrate 10 is a silicon interposer substrate and the second substrate 20 is an LTCC substrate or a PCB substrate, since there is a great difference in a dielectric value between them, signal loss may occur more significantly.

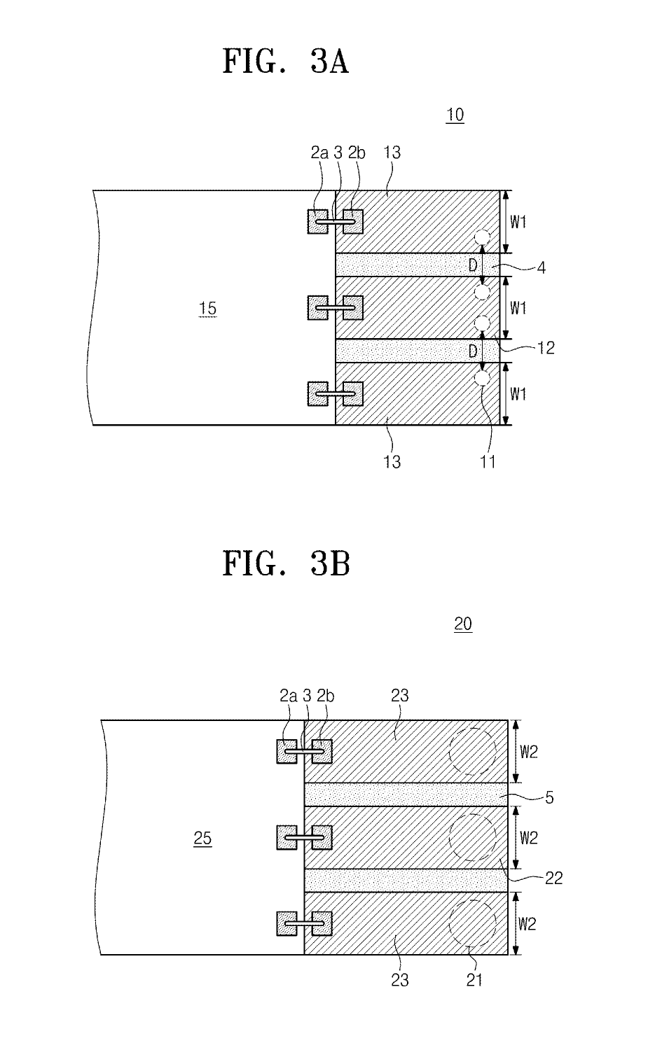

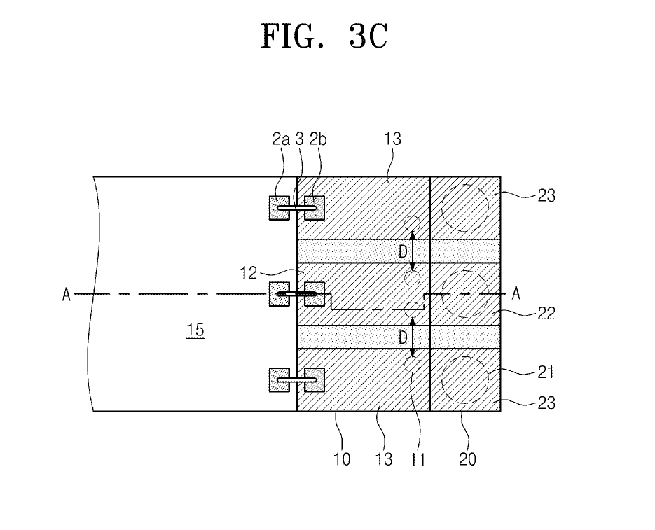

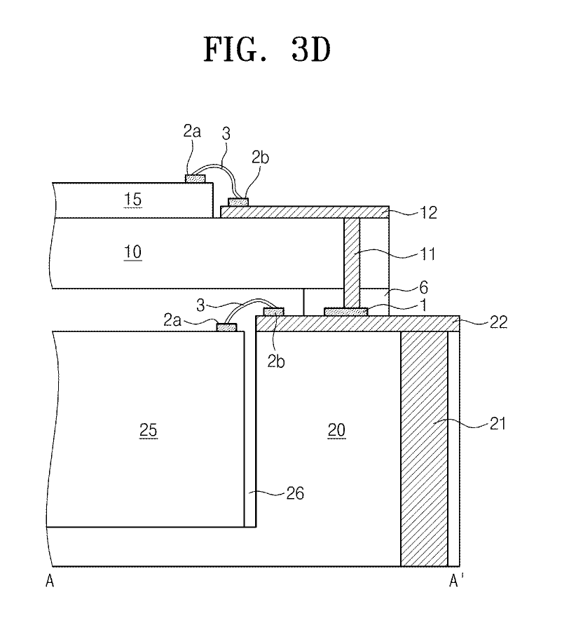

FIG. 3A is a plan view of a first substrate 10 where a first device 15 is mounted according to an embodiment of the present invention. FIG. 3B is a plan view of a second substrate 20 where a second device 25 is mounted according to an embodiment of the present invention. Referring to FIGS. 3A and 3B, provided are the first substrate 10 where the first device 15 is mounted and the second substrate 20 where the second device 25 having a greater thickness than the first device 15 is mounted. The second substrate 20 may have a greater thickness than the first substrate 10 in order to mount the second device 25.

Unlike FIG. 2A, in relation to the first substrate 10, each width W1 of the first conductive patterns 12 and 13 may be formed to satisfy a predetermined characteristic impedance. In more detail, the width W1 of each of the first signal patterns 12 and the first ground patterns 13 may be formed to satisfy a predetermined characteristic impedance. The predetermined characteristic impedance may be defined by the second conductive patterns 22 and 23 of the second substrate 20. In more detail, the predetermined character impedance may be defined by the widths W2 and intervals therebetween of the second signal patterns 22 and the second ground patterns 23. According to an embodiment of the present invention, the width W1 of each of the first signal patterns 12 and the first ground patterns 13 may be identical to the width W2 of each of the second signal patterns 22 and the second ground patterns 23.

A plurality of first vias 11 may be connected to each of the first signal patterns 12 and/or the first ground patterns 13. According to an embodiment of the present invention, two first vias 11 are connected to each of the first signal patterns 12 and one first via 11 may be connected to each of the first ground patterns 13. As described above, compared to FIG. 2A, the width W1 of each of the first signal patterns 12 and the first ground patterns 13 on the first substrate 10 may become greater. In this case, when one first via 11 is connected to each of the first signal patterns 12 and the first ground patterns 13, a distance D between adjacent first vias 11 may be become further away. That is, as the distance D is further away, since it is difficult to satisfy a predetermined characteristic impedance value corresponding to the second substrate 20, signal loss may occur more significantly. On the other hand, according to the present invention, since the plurality of first vias 11 are connected to the first signal pattern 12 and/or the first ground pattern 13, even when the width W1 of each of the first signal patterns 12 and the first ground patterns 13 becomes greater, the distance D between adjacent first vias 11 may be reduced. That is, by adjusting the distance D between the first via 11 connected to the first ground pattern 13 and the first via 11, which is directly adjacent thereto, connected to the first signal pattern 12, a predetermined characteristic impedance may be satisfied. Additionally, the yield of a package may be increased by using the plurality of first vias 11. This is because, when a part of the first vias 11 is not connected to the first signal patterns 12 and/or the first ground patterns 13 due to defects during manufacturing processes, the remaining first vias 11 may form an electrical path.

Moreover, according to an embodiment, one second via 21 may be connected to each of the second signal patterns 22 and the second ground patterns 23 of the second substrate 20. That is, in correspondence to one second via 21 connected to the second signal pattern 22, more than two first vias 11 may be connected to each of the signal patterns 12.

As a result, the present invention forms the width W1 of each of the first signal pattern 12 and the first ground pattern 13 of the first substrate 10 and the distance D between the first vias 11 to correspond to a predetermined characteristic impedance value that the second substrate 20 has, so that signal loss may be minimized when the first substrate 10 and the second substrate 20 are connected vertically. Additionally, they may be easily and vertically connected in terms of physical structure.

Besides that, details on the first substrate 10 having the first device 15 mounted thereon and the second substrate 20 having the second device 25 mounted thereon may be identical to those described with reference to FIGS. 2A and 2B.

FIG. 3C is a plan view of a stack module package according to an embodiment of the present invention. FIG. 3D is a sectional view taken along a line A-A′ of FIG. 3C.

Referring to FIGS. 3C and 3D, a stack module package according to an embodiment of the present invention may include a first substrate 10 where a first device 15 is mounted and a second substrate 20 where a second device 25 is mounted. The second substrate 20 may have a greater thickness than the first substrate 10. The second device 25 may have a greater thickness than the first device 15. Furthermore, the first substrate 10 may include first vias 11 penetrating it. Additionally, the first substrate 10 may include first conductive patterns 12 and 13 formed on the first substrate 10 and connected to the first device 15. The first conductive patterns 12 and 13 may include first signal patterns 12 and first ground patterns 13. Each of the first signal patterns 12 and/or the first ground patterns 13 may be connected to the plurality of first vias 11. Furthermore, the second substrate 20 may include second vias 21 penetrating it. Additionally, the second substrate 20 may include second conductive patterns 22 and 23 formed on the second substrate 20 and connected to the second device 25. The second conductive patterns 22 and 23 may include second signal patterns 22 and second ground patterns 23. Each of the second signal patterns 22 and the second ground patterns 23 may be connected to at least one second via 21. A second cavity 26 recessed toward the bottom of the second substrate 20 may be formed in the second substrate 20 in order to mount the second device 25. Therefore, the second device 25 may be seated in the second cavity 26. An underfill 6 may be interposed between the first substrate 10 and the second substrate 20.

The first substrate 10 and the second substrate 20 may be vertically connected to each other through the first vias 11 and the second vias 21, respectively. In more detail, the first signal pattern 12 and the second signal pattern 22 are vertically connected to each other through the first vias 11 and the second vias 21, so that high frequency signals or high speed electrical signals may be delivered. The first ground pattern 13 and the ground pattern 23 are vertically connected to each other through the first vias 11 and the second vias 21, so that high frequency signals or high speed electrical signals may be delivered. For example, the second signal pattern 22 may be connected to the second device 25 and the second via 21. A connection part 1 may be disposed on the second signal pattern 22 and the first via 11 may be disposed on the connection part 1 to be connected thereto. The first signal pattern 12 may be connected to the first device 15 and the first via 11. Therefore, the first signal pattern 12 and the second signal pattern 22 may be vertically connected to each other. Additionally, the first device 15 and the second device 25 may be vertically connected to each other. When signals are applied from the second via 21, they may be delivered sequentially through the second via 21, the second signal pattern 22, the first via 11, and the first signal pattern 12, and in addition to this, the signals may be delivered to the second device 25 and the first device 15. As described above, the present invention may minimize signal loss when the first substrate 10 and the second substrate 20 are connected vertically.

Besides that, details on the first substrate 10 having the first device 15 mounted thereon and the second substrate 20 having the second device 25 mounted thereon may be identical to those described with reference to FIGS. 3A and 3B.

### Embodiment 1

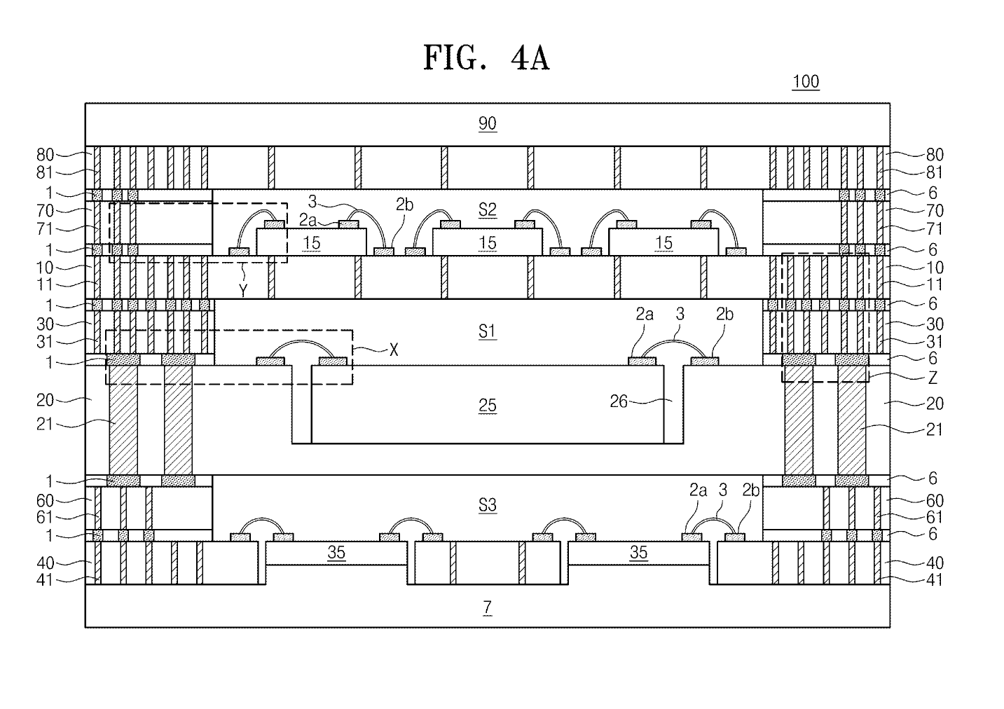

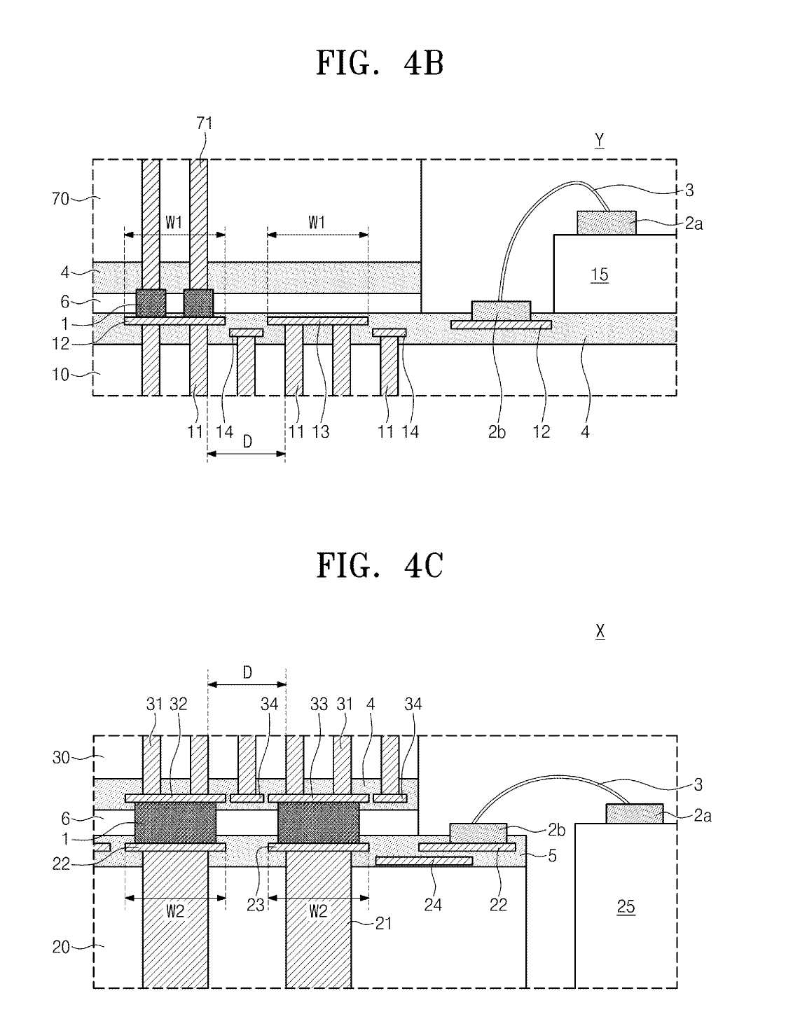

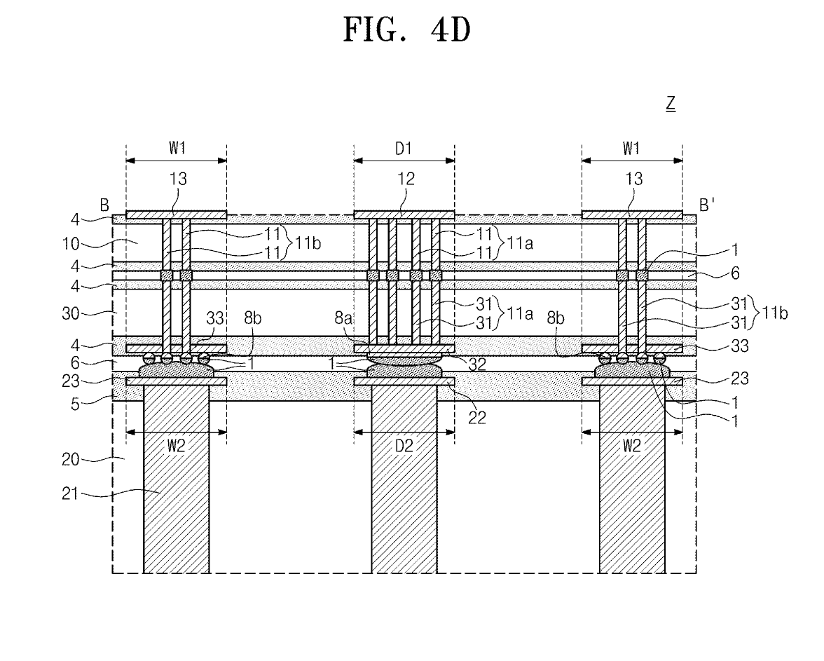

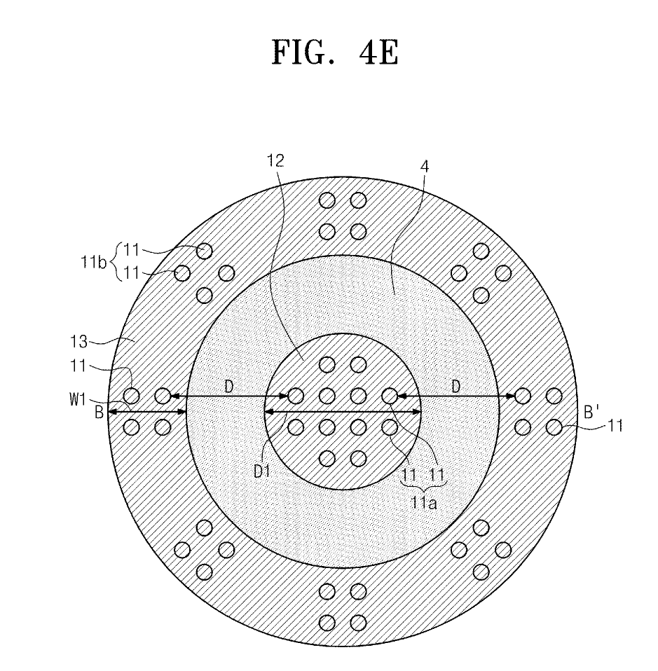

FIG. 4A is a sectional view of a stack module package 100 according to the embodiment 1 of the present invention. FIG. 4B is an enlarged sectional view of an area Y in FIG. 4A. FIG. 4C is an enlarged sectional view of an area X in FIG. 4A.

Referring to FIGS. 4A, 4B, and 4C, the stack module package 100 according to the embodiment 1 may include a first substrate 10 where first devices 15 are mounted and a second substrate 20 where a second device 25 is mounted. The second substrate 20 may have a greater thickness than the first substrate 10. The second device 25 may have a greater thickness than the first devices 15.

The first substrate 10 may include first vias 11 penetrating it. Additionally, the first substrate 10 may include first signal patterns 12 and first ground patterns 13, which are formed on the first substrate 10 and connected to the first device 15. Each of the first signal patterns 12 and the first ground patterns 13 may be connected to the plurality of first vias 11. A protective layer 4 may be formed on the first substrate 10 and in more detail, may be formed on the top surface and bottom surface of the first substrate 10. Connection parts 1 may be disposed on the first signal patterns 12 and the first ground patterns 13 connected to the first vias 11. Through the connection parts 1 disposed on the top surface of the first substrate 10, the first vias 11 may be vertically connected to seventh vias 71. Additionally, through the connection parts 1 disposed on the bottom surface of the first substrate 10, the first vias 11 may be vertically connected to third vias 31. The connection parts 1 may include a solder ball, a solder cap, or a solder bump. First rewiring layers 14 may be formed on the first substrate 10. Each of the first rewiring layers 14 may be connected to the first via 11 so that electrical and/or high frequency signals may be delivered to the first rewiring layers 14 through the first via 11. Furthermore, the first signal patterns 12, the first ground patterns 13, and the first rewiring layers 14 may be formed on the top surface and bottom surface of the first substrate 10, and may be surrounded by the protective layer 4. According to an embodiment of the present invention, the first via 11 may be a silicon through hole and the first substrate 10 may be a silicon interposer substrate.

Device connection terminals 2a may be disposed on each of the first devices 15 and substrate connection terminals 2b may be disposed on each of the first signal patterns 12 and the first ground patterns 13. The device connection terminals 2a and the substrate connection terminals 2b may be connected to each other through a wire 3. Therefore, each of the first devices 15 may be connected to the first signal patterns 12 and the first ground patterns 13. As described above, the first devices 15 may be horizontally connected to the first substrate 10 through the wire 3 or may be vertically connected to the first substrate 10 by using a solder ball (not shown). Although not shown in the drawing, a connection pad (not shown) and a solder ball (not shown) may be disposed on the bottom surface of each of the first devices 15 and the first devices 15 may be mounted on the first substrate 10. Therefore, each of the first devices 15 may be electrically connected to the first signal patterns 12 and the first ground patterns 13. The first devices 15 may be selected from devices configuring an RF module, and for example, may be selected from the group including a core chip CC, a driving amplifier DA, an attenuator AT, a power amplifier PA, a limiter LI, a low noise amplifier LNA, and a filter FI.

Moreover, the second substrate 20 may include second vias 21 penetrating it. Additionally, the second substrate 20 may include second signal patterns 22 and second ground patterns 23, which are formed on the first substrate 20 and connected to the second device 25. Each of the second signal patterns 22 and the second ground patterns 23 may be connected to at least one second via 21. An insulation layer 5 may be formed on the second substrate 20 and in more detail, may be formed on the top surface and bottom surface of the second substrate 20. Connection parts 1 may be disposed on the second signal patterns 22 and the second ground patterns 23. Through the connection parts 2 disposed on the top surface of the second substrate 20, the second vias 21 may be vertically connected to third vias 31. Additionally, through the connection parts 2 disposed on the bottom surface of the second substrate 20, the second vias 21 may be vertically connected to sixth vias 61. The connection parts 1 may include a solder ball, a solder cap, or a solder bump. Second rewiring layers 24 may be formed on the second substrate 20. Each of the second rewiring layers 24 may be connected to the second via 21 so that electrical and/or high frequency signals may be delivered to the second rewiring layers 24 through the second via 21. Furthermore, the second signal patterns 22, the second ground patterns 23, and the second rewiring layers 24 may be formed on the top surface and bottom surface of the second substrate 20, and may be surrounded by the insulation layer 5. A second cavity 26 recessed toward the bottom of the second substrate 20 may be formed in the second substrate 20 in order to mount the second device 25. Since the second substrate 20 has a greater thickness than the first substrate 10, the second device 25 having a greater thickness than the first devices 15 may be mounted effectively. The second device 25 may be seated in the second cavity 26. According to an embodiment of the present invention, each of the second vias 21 may be a vertical connection channel where a through hole is filled with a conductive material. Each of the second vias 21 may have a greater diameter than the first vias 11. The second substrate 20 may be a ceramic substrate such as an LTCC substrate or a plastic substrate such as a PCB substrate.

Device connection terminals 2a may be disposed on the second device 25 and substrate connection terminals 2b may be disposed on each of the second signal patterns 22 and the second ground patterns 23. The device connection terminals 2a and the substrate connection terminals 2b may be connected to each other through a wire 3. Therefore, each of the second devices 25 may be connected to the second signal patterns 22 and the second ground patterns 23. As described above, the second device 25 may be horizontally connected to the second substrate 10 through the wire 3 or may be vertically connected to the second substrate 20 by using a solder ball (not shown). Although not shown in the drawing, a connection pad (not shown) and a solder ball (not shown) may be disposed on the bottom surface of each of the second device 25 and the second device 25 may be mounted on the second substrate 20. Therefore, the second device 25 may be electrically connected to the second signal patterns 22 and the second ground patterns 23. The second device 25 may be selected from devices configuring an RF module, but may have a greater thickness than the first device 15. For example, the second device 25 may be a circulator CI.

A stack module package 100 according to the embodiment 1 may further include a third substrate 30 interposed between the first substrate 10 and the second substrate 20. The third substrate 30 may vertically and electrically connect the first substrate 10 and the second substrate 20. In more detail, the third substrate 30 may provide a first space 51 between the bottom surface of the first substrate 10 and the top surface of the second substrate 20. Therefore, the first space S1 where device connection terminals 2a, substrate connection terminals 2b, and wires 3 connecting the first device 25 and the second substrate 20 are disposed may be provided between the first substrate 10 and the second substrate 10. As described above, when the height of the top surface of the second device 25 is identical to or lower than that of the second substrate 20 and the second device 25 and the second substrate 20 are connected through the connection pad and the solder ball, the third substrate 30 may be omitted.

The third substrate 30 may be thinner than the second substrate 20. The third substrate 30 may include third vias 31 penetrating it and connecting the first vias 11 and the second vias 21. Additionally, the third substrate 30 may include third signal patterns 32 and third ground patterns 33, which are formed on the third substrate 30 and connected to the third device 31. Third rewiring layers 34 may be formed on the third substrate 30. Each of the third rewiring layers 34 may be connected to the third via 31. Furthermore, the third signal patterns 32, the third ground patterns 33, and the third rewiring layers 34 may be formed on the top surface and bottom surface of the third substrate 30. Except that devices are not mounted on the third substrate 30, the third substrate 30 may be identical to the above-described first substrate 10.

The first substrate 10 and the second substrate 20 may be vertically connected to each other through the first vias 11 and the second vias 21, respectively. In more detail, the first substrate 10 and the second substrate 20 may be vertically connected to each other through the third substrate 30 and this may be achieved through a connection between the first vias 11, the second vias 21, and the third vias 31. As described above, the third substrate 30 is only intended to provide a first space Si between the first substrate 10 and the second substrate 20 and substantially may have the same characteristics as the first substrate 10.

In relation to the first substrate 10 and the third substrate 30, the width W1 of each of the first signal patterns 12, the first ground patterns 13, the third signal patterns 32, and the third ground patterns 33 may be formed to satisfy a predetermined characteristic impedance. The predetermined characteristic impedance may be defined by the second signal patterns 22 and the second ground patterns 23 of the second substrate 20. According to an embodiment of the present invention, the width W1 of each of the first signal patterns 12, the first ground patterns 13, the third signal patterns 32, and the third ground patterns 33 may be identical to the width W2 of each of the second signal patterns 22 and the second ground patterns 23 but the present invention is not limited thereto.

A plurality of first vias 11 may be connected to each of the first signal patterns 12 and/or the first ground patterns 13. A plurality of third vias 31 may be connected to each of the third signal patterns 32 and/or the third ground patterns 33. According to an embodiment of the present invention, two first vias 11 may be connected to each of the first signal patterns 12 and the first ground patterns 13, and two third vias 31 may be connected to each of the third signal patterns 31 and the third ground patterns 32. As described with reference to FIG. 3A, a distance D between a first via 11 connected to the first ground pattern 13 and a first via 11 adjacent thereto directly and connected to the first signal pattern 12 may be adjusted. In such a manner, a distance D between a third via 31 connected to the third ground pattern 33 and a third via 31 adjacent thereto directly and connected to the third signal pattern 32 may be adjusted. By adjusting the distance D, a predetermined characteristic impedance may be satisfied.

At least one second via 21 may be connected to each of the second signal patterns 22 and the second ground patterns 23 of the second substrate 20. According to an embodiment of the present invention, one second via 21 may be connected to each of the second signal patterns 22 and the second ground patterns 23.

The second substrate 20 and the third substrate 30 may be vertically connected to each other through the second vias 21 and the third vias 31. For example, the second signal pattern 22 may be connected to the second device 25 and the second via 21. A connection part 1 may be disposed on the second signal pattern 22 and the third via 31 may be disposed on the connection part 1 to be connected thereto. The third signal pattern 32 may be disposed between the connection part 1 and the third via 31 but the present invention is not limited thereto. An underfill 6 may be interposed between the insulation layer 5 of the second substrate 20 and the protective layer 4 of the third substrate 30 to protect the connection part 1.

The first substrate 10 and the third substrate 30 may be vertically connected to each other through the first vias 11 and the third vias 31. A connection part 1 may be disposed between the first vias 11 and the third vias 31, so that the first vias 11 and the third vias 31 may be electrically connected to each other. An underfill 6 may be interposed between the protective layer 4 of the first substrate 10 and the protective layer 4 of the third substrate 30, thereby protecting the connection part 1.

In this embodiment 1, a signal delivery through the first substrate 10 to third substrate 30 is described exemplarily. When signals are applied from the second via 21, they may be delivered sequentially through the second via 21, the second signal pattern 22, the connection part 1, the third signal pattern 32, and the third via 31. Then, the signals may be delivered sequentially through the third via 31, the connection part 1, the first via 11, and the first signal pattern 12. In addition, the signals may be delivered to the second device 25 and the first device 15. As described above, the present invention may minimize signal loss when the first substrate 10 and the third substrate 30 are connected vertically.

The stack module package 100 according to the embodiment 1 may further include a fourth substrate 40 disposed below the second substrate 20 and horizontally connected to the third devices 35 and a thermal dissipation plate 7 disposed blow the fourth substrate 40 and dissipating the heat generated from the third devices 35.

The fourth substrate 40 may be thinner than the second substrate 20. The fourth substrate 40 may include fourth vias 41 penetrating it and connected to the six vias 61. Additionally, the fourth substrate 40 may include fourth signal patterns (not shown) and fourth ground patterns (not shown), which are formed on the fourth substrate 30 and connected to the fourth via 41. Except that devices are not mounted on the fourth substrate 40, the fourth substrate 40 may be identical to the above-described first substrate 10.

Each of the third devices 35 may be disposed on the thermal dissipation plate 7 to directly contact the thermal dissipation plate 7. Device connection terminals 2a may be disposed on each of the third devices 35 and substrate connection terminals 2b may be disposed on each of the fourth signal patterns (not shown) and the fourth ground patterns (not shown). The device connection terminals 2a and the substrate connection terminals 2b may be connected to each other through a wire 3. Therefore, each of the third devices 35 may be connected to the fourth signal patterns (not shown) and the fourth ground patterns (not shown).

The third devices 35 may be selected from devices configuring an RF module but may be selected from devices that consume high power. For example, each of the third devices 35 may be a driving amplifier DA or a power amplifier PA. At this point, the heat dissipation plate 7 may efficiently discharge the heat generated from the third devices 35 to the outside by directly contacting the third devices 35.

The stack module package 100 according to the embodiment 1 may further include a sixth substrate 60 interposed between the second substrate 20 and the fourth substrate 40, an eighth substrate 80 disposed on the first substrate 10, and a seventh substrate 70 interposed between the eighth substrate 80 and the first substrate 10.

Each of the sixth substrate 60, the seventh substrate 70, and the eighth substrate 80 may be thinner than the second substrate 20. The sixth substrate 60 may vertically and electrically connect the second substrate 20 and the fourth substrate 40. In more detail, the sixth substrate 60 may provide a third space S3 between the bottom surface of the second substrate 20 and the top surface of the fourth substrate 40. The seventh substrate 70 may vertically and electrically connect the eighth substrate 80 and the first substrate 10. In more detail, the seventh substrate 70 may provide a second space S2 between the bottom surface of the eighth substrate 80 and the top surface of the first substrate 10. Each of the sixth substrate 60 and the seventh substrate 70 may be identical to the above-described third substrate 30. Except that devices are not mounted on the eighth substrate 80, the eighth substrate 80 may be identical to the above-described first substrate 10

A driving module 90 may be disposed on the eighth substrate 80. The driving module 90 may be electrically connected to the eighth substrate 80. Furthermore, the driving module 90 may be electrically connected to the first devices 15, the second device 25, and the third devices 35 through the above-described substrates and vias. The stack module package 100 where the driving module 90 is disposed according to the embodiment 1 may be sealed by a metal housing (not shown).

The stack module package 100 according to the embodiment 1 may have an advantageous structure in terms of heat. That is, heat may be dissipated to the outside smoothly by disposing the third devices 35, which consume high power and thus have a high operating temperature, on the thermal dissipation plate 7. Moreover, by disposing the second substrate 20 having a low thermal conductivity value on the third devices 35, the second substrate 20 may provide a thermal insulation effect of blocking the heat generated from the third devices 35. Therefore, the first devices 15 and the second device 25 may be protected from the heat generated from the third devices 35.

FIG. 4D is an enlarged sectional view of an area Z in FIG. 4A and illustrates an electrical connection relationship between the first substrate 10, the second substrate 20, and the third substrate 30 according to another embodiment of the present invention. FIG. 4E is a plan view taken along a line B-B′ of FIG. 4D.

Referring to FIGS. 4D and 4E, the first substrate 10, the second substrate 20, and the third substrate 30 may be vertically connected through a coaxial transmission line structure. Hereinafter, differences from the description of a connection relation of the first substrate 10, the second substrate 20, and the third substrate 30 will be mainly described.

In more detail, the first ground pattern 13 may surround the first signal pattern 12 to form a closed curve. However, the first ground pattern 13 may be spaced from the first signal pattern 12. For example, the first signal pattern 12 may have a circular form in a plane and the first ground pattern 13 may have a donut form surrounding the first signal pattern 12 in a plane. A protective layer 4 may be interposed between the first signal pattern 12 and the first ground pattern 13. Although not shown in the drawing, the first signal pattern 12 and the first ground pattern 13 may be connected to the first device 15 and this may be electrically connected through the first rewiring layers 14. The first signal pattern 12 may be connected to a first bundle 11a including a plurality of first vias 11. The first ground pattern 13 may be connected to a second bundle 11b including a plurality of first vias 11. The second bundle 11b may be in plurality. The first bundle 11a extends to the third substrate 30 through the connection parts 1 and then may be connected to the third signal pattern 32. The second bundles 11b extends to the third substrate 30 through the connection parts 1 and then may be connected to the third ground patterns 33. The planar forms of the third signal pattern 32 and the third ground pattern 33 may be identical to those of the above-described first signal patterns 12 and the first ground patterns 13. A first conductive pillar 8a and a connection part 1 may be disposed at the bottom surface of the third signal pattern 32. The connection part 1 may be connected to one terminal of the first conductive pillar 8a and may be a solder cap. The first conductive pillar 8a and the connection part 1 may be electrically connected to the first bundle 11a. A plurality of second conductive pillars 8b and connection parts 1 may be disposed at the bottom surface of the third ground pattern 33. Each of the connection parts 1 may be connected to one terminal of the second conductive pillars 8b and may be a solder cap. The second conductive pillars 8b and the connection parts a may be electrically connected to the second bundles 11b.

The second ground pattern 23 may surround the second signal pattern 22 to form a closed curve. However, the second ground pattern 23 may be spaced from the second signal pattern 22. The planar forms of the second signal pattern 22 and the second ground pattern 23 may be identical to those of the above-described first signal patterns 12 and the first ground patterns 13. An insulation layer 5 may be interposed between the second signal pattern 22 and the second ground pattern 23. Although not shown in the drawing, the second signal pattern 22 and the second ground pattern 23 may be connected to the second device 25 and this may be electrically connected through the second rewiring layers 24. The second signal pattern 22 may be connected to a second via 21. The second ground pattern 23 may be connected to second vias 21. Connection parts 1 may be disposed on the second signal patterns 22 and the second ground patterns 23. Each of the connection parts 1 may be a solder cap.

In relation to the first substrate 10 and the third substrate 30, the diameter D1 of each of the first signal pattern 12 and the third signal pattern 32 and the width W1 of each of the first ground pattern 13 and the third ground pattern 33 may be formed to satisfy a predetermined characteristic impedance. The predetermined characteristic impedance may be defined by the second signal pattern 22 and the second ground pattern 23 of the second substrate 20. According to an embodiment of the present invention, the diameter D1 of each of the first signal pattern 12 and the third signal pattern 32 may be identical to the diameter D2 of the second signal pattern 22. Then, the width W1 of each of the first ground pattern 13 and the third ground pattern 33 may be identical to the width W2 of the second ground pattern 23 but the present invention is not limited thereto.

According to this embodiment, a distance D between a first via 11 connected to the first ground pattern 13 and a first via 11 adjacent thereto directly and connected to the first signal pattern 12 may be adjusted by using the first bundle 11a and the second bundle 11b including the first vias 11. That is, the distance D between the first via 11 of the first bundle 11a and the first via 11 of the second bundle 11 adjacent thereto directly may be adjusted to satisfy a predetermined characteristic impedance.

In this embodiment, a signal delivery through the first substrate 10 to third substrate 30 is described exemplarily. When signals are applied from the second via 21, they may be delivered sequentially through the second via 21, the second signal pattern 22, the connection part 1, the first conductive pillar 8a, the third signal pattern 32, the first bundle 11a, and the first signal pattern 12. In addition, the signals may be delivered to the second device 25 and the first device 15. As described above, the present invention may minimize signal loss when the first substrate 10 and the third substrate 30 are connected vertically. Especially, by achieving a connection between the first substrate 10 to the third substrate 30 through a coaxial transmission line, when signals are delivered from the second substrate 20 to the third substrate 30 and the first substrate 10, an impedance change may be minimized. That is, according to the present invention, signal loss may be minimized during a vertical signal delivery between substrates having different characteristics.

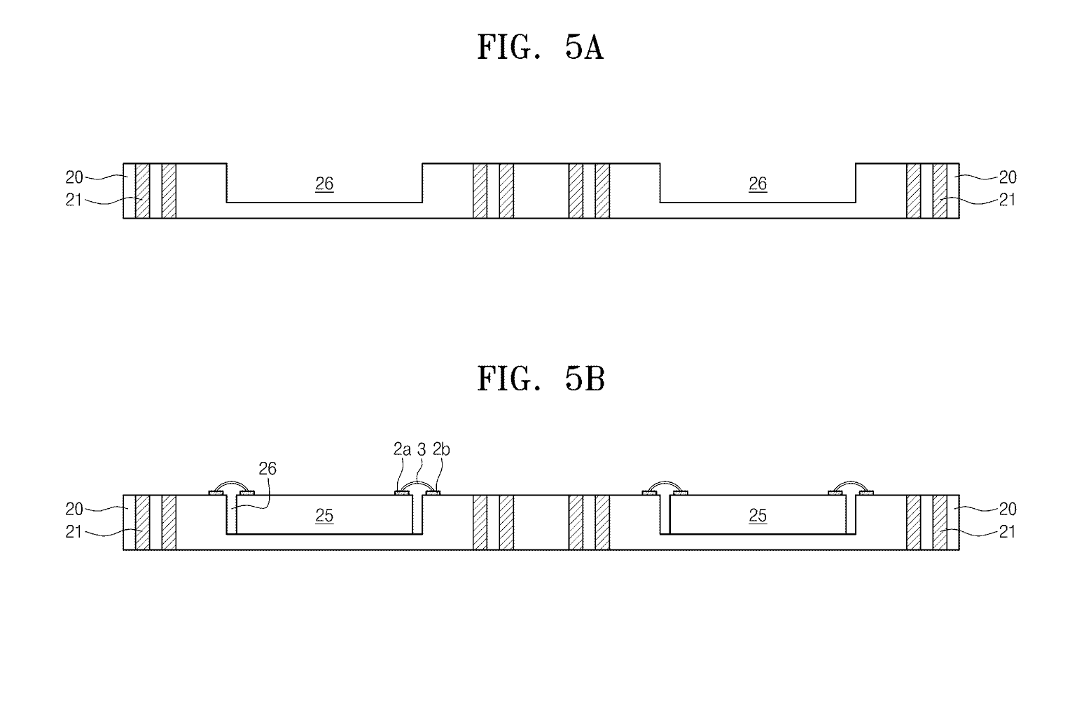

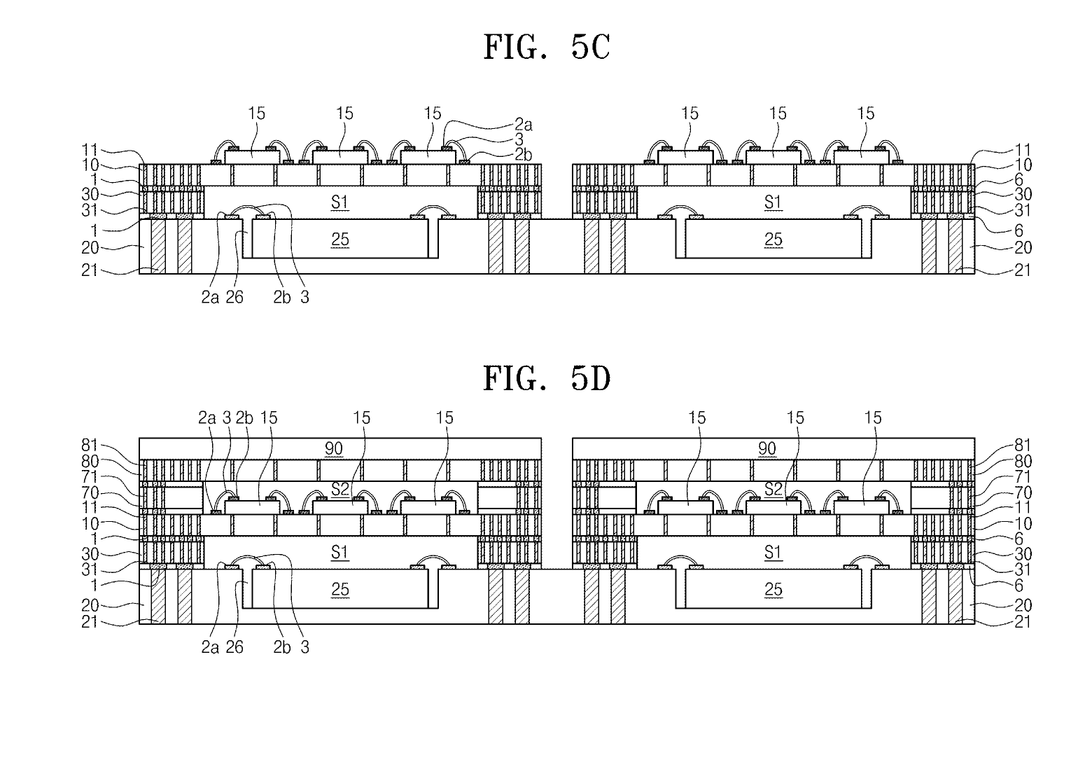

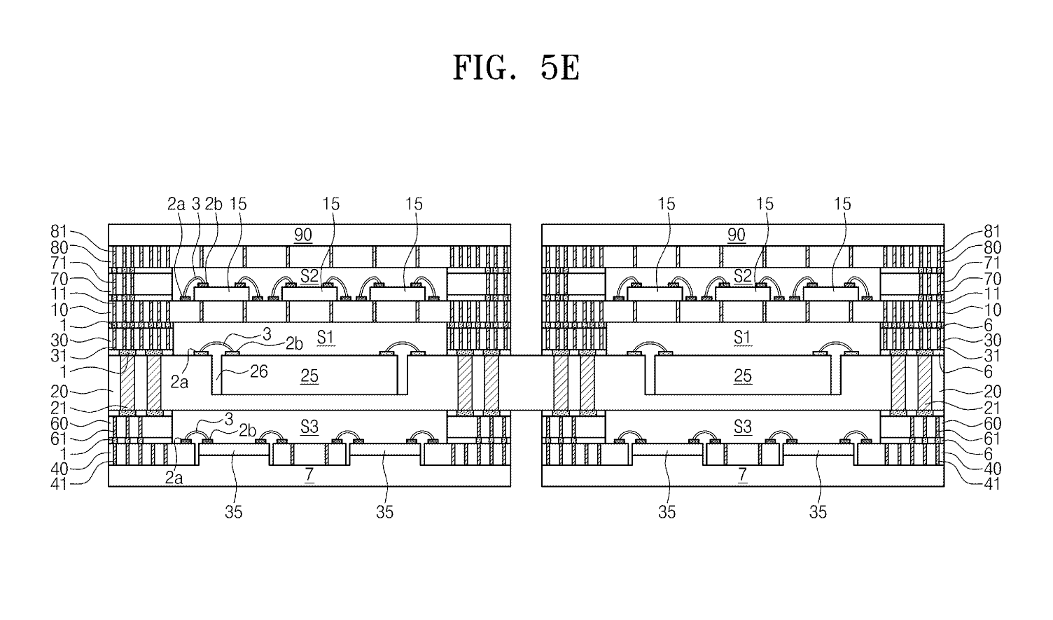

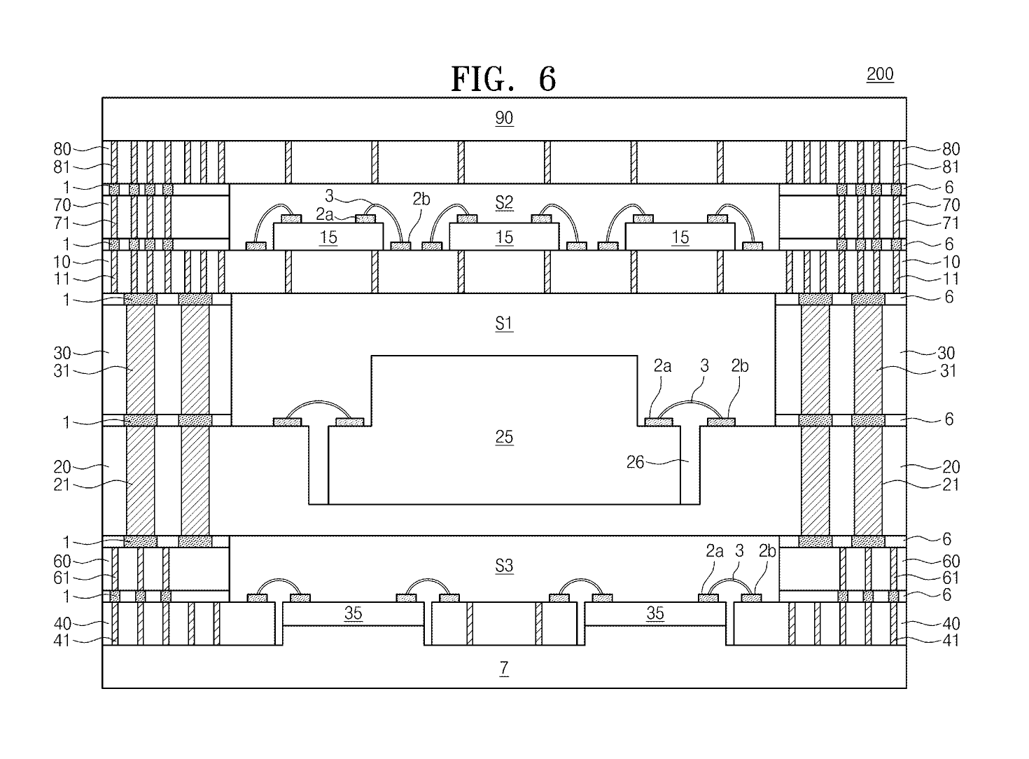

FIGS. 5A to 5E are sectional views illustrating processes for sequentially manufacturing the stack module package 100 according to the embodiment 1.

Referring to FIG. 5A, a second substrate 20 may be prepared first as a carrier substrate. The second substrate 20 may include second vias 21 penetrating it. Additionally, the second substrate 20 may include second signal patterns 22 and second ground patterns 23 thereon (see FIG. 4C). A second cavity 26 recessed toward the bottom of the second substrate 20 may be formed in the second substrate 20 in order to mount the second device 25. The second cavity 26 may be formed through a mechanical polishing process or laser. The second substrate 20 may be a ceramic substrate such as an LTCC substrate or a plastic substrate such as a PCB substrate. Besides that, details for the second substrate 20 are described above with reference to FIGS. 4A, 4B, and 4C.

Referring to FIG. 5B, second devices 25 may be mounted on the second substrate 20 through die-bonding. The second device 25 may be seated in the second cavity 26. Device connection terminals 2a may be formed on the second device 25 and substrate connection terminals 2b may be formed on each of the second signal patterns 22 and the second ground patterns 23 (see FIG. 4C). The device connection terminals 2a and the substrate connection terminals 2b may be connected to each other through a wire 3. Besides that, details for the second device 25 are described above with reference to FIGS. 4A, 4B, and 4C.

Referring to FIG. 5C, a third substrate 30 and a first substrate 10 may be sequentially disposed on the second substrate 20. First, the third substrate 30 may be disposed on the second substrate 20 and at this point, an underfill 6 may be formed between the second substrate 20 and the third substrate 30. The third substrate 30 may be thinner than the second substrate 20. The third substrate 30 may include third vias 31 penetrating it and connected to the second vias 21. Additionally, the third substrate 30 may include third signal patterns 32 and third ground patterns 33 thereon (see FIG. 4C).

The first substrate 10 may be disposed on the third substrate 30 and at this point, an underfill 6 may be formed between the first substrate 10 and the third substrate 30. The first substrate 10 may be thinner than the second substrate 20. The first substrate 10 may include first vias 11 penetrating it and connected to the third vias 31. Additionally, the first substrate 10 may include first signal patterns 12 and first ground patterns 13 thereon (see FIG. 4B).

First devices 15 may be mounted on the first substrate 10 through die bonding. Device connection terminals 2a may be formed on the first device 15 and substrate connection terminals 2b may be formed on each of the first signal patterns 12 and the second ground patterns 23 (see FIG. 4B). The device connection terminals 2a and the substrate connection terminals 2b may be connected to each other through a wire 3.

Besides that, details for the first substrate 10, the third substrate 30, and the first devices 15 are described above with reference to FIGS. 4A, 4B, and 4C.

Referring to FIG. 5D, after mounting the first devices 15 on the first substrate 10, a seventh substrate 70 and an eighth substrate 80 may be sequentially disposed on the first substrate 10. First, the seventh substrate 70 may be disposed on the first substrate 10 and at this point, an underfill 6 may be formed between the first substrate 10 and the seventh substrate 70. Then, the eighth substrate 80 may be disposed on the seventh substrate 70 and at this point, an underfill 6 may be formed between the seventh substrate 70 and the eighth substrate 80.

A driving module 90 may be disposed on the eighth substrate 80. The driving module 90 may be electrically connected to the eighth substrate 80.

Besides that, details for the seventh substrate 70, the eighth substrate 80, and the driving module 90 are described above with reference to FIGS. 4A, 4B, and 4C.

Referring to FIG. 5E, a sixth substrate 60 and a fourth substrate 40 may be sequentially disposed below the second substrate 20.

First, the sixth substrate 60 may be disposed below the second substrate 20 and at this point, an underfill 6 may be formed between the second substrate 20 and the sixth substrate 60. The sixth substrate 60 may be thinner than the second substrate 20. The sixth substrate 60 may include sixth vias 61 penetrating it and connected to the second vias 21. Additionally, the sixth substrate 60 may include sixth signal patterns (not shown) and sixth ground patterns (not shown) formed thereon.

Then, a thermal dissipation plate 7 where a fourth substrate 40 is disposed may be prepared thereon. The fourth substrate 40 may be thinner than the second substrate 20.

The fourth substrate 40 may include fourth vias 41 penetrating it and connected to the second vias 21. Additionally, the fourth substrate 40 may include fourth signal patterns (not shown) and fourth ground patterns (not shown) formed thereon. Third devices 35 may be disposed on the thermal dissipation plate 7 and may directly contact the thermal dissipation plate 7. Device connection terminals 2a may be formed on the third device 35 and substrate connection terminals 2b may be formed on each of the fourth signal patterns (not shown) and the fourth ground patterns (not shown). The device connection terminals 2a and the substrate connection terminals 2b may be connected to each other through a wire 3.

The prepared thermal dissipation plate 7 having the fourth substrate 40 disposed thereon first substrate 40 may be disposed below the sixth substrate 60 and at this point, an underfill 6 may be formed between the sixth substrate 60 and the fourth substrate 40.

Besides that, details for the sixth substrate 60, the fourth substrate 40, the third devices 35, and the thermal dissipation plate 7 are described above with reference to FIGS. 4A, 4B, and 4C.

Referring to FIG. 4A subsequently, a singulation process for cutting the substrate 20 and separating it by each unit module package may be performed. The singulation process may be performed by using a diamond cutting edge. Therefore, the stack module package 100 according to the embodiment 1 of the present invention may be completed.

Subsequently, the stack module package 100 according to the embodiment 1 may be mounted in a metal housing (not shown).

A method of manufacturing a stack module package according to an embodiment of the present invention may obtain a module arrangement in which the position and interval of an RF connector are uniform and also add necessary test processes during an individual process to increase the yield. Additionally, by using the second substrate 20 disposed in a stack module package as a carrier substrate, processes may be simplified.

### Embodiment 2

FIG. 6 is a sectional view of a stack module package 200 according to the embodiment 2 of the present invention.

Referring to FIG. 6, the stack module package 200 according to the embodiment 2 may include a third substrate 30 interposed between a first substrate 10 and a second substrate 20 and having a greater thickness than the first substrate 10. The third substrate 30 may further include third vias 31 penetrating it and connecting the first vias 11 and the second vias 21 and each of the third vias 31 may have a greater diameter than each of the first vias 11. The third substrate 30 may vertically and electrically connect the first substrate 10 and the second substrate 20 through the third vias 31. In more detail, the third substrate 30 may provide a first space 51 between the bottom surface of the first substrate 10 and the top surface of the second substrate 20. Therefore, a first space 51 where a second device 25 is to be disposed may be provided between the first substrate 10 and the second substrate 20. Unlike the second device 25 according to the above embodiment 1, the second device 25 in this embodiment 2 may have a greater thickness. In this case, it is necessary to use a substrate having a greater thickness than the third substrate 30 according to the embodiment 1. In more detail, in the embodiment 2, a level of the top surface of the second device 25 may be disposed between the top surface and bottom surface of the third substrate 30. Except that devices are not mounted on the third substrate 30, the third substrate 30 may be identical to the second substrate 20 described in the above embodiment 1. A connection relationship between the third substrate 30 and the first substrate 10 may be identical to that between the second substrate 20 and the third substrate 30 described in the above embodiment 1. The other configurations are the same as previously described in the above embodiment 1

Embodiment 3

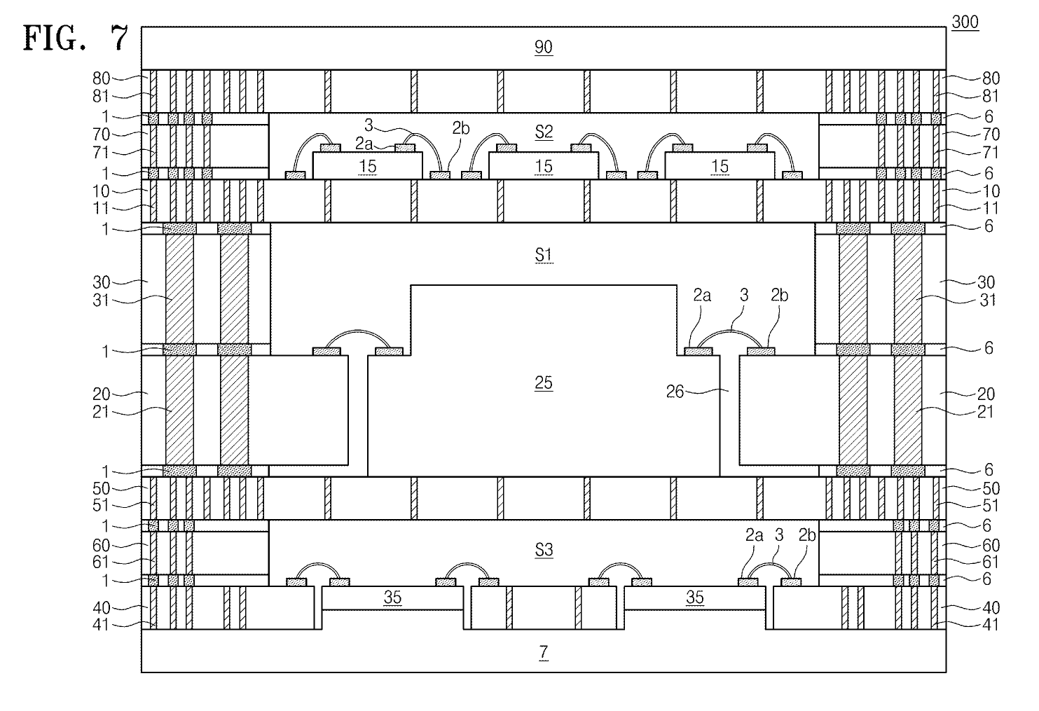

FIG. 7 is a sectional view of a stack module package 300 according to the embodiment 3 of the present invention.

Referring to FIG. 7, the stack module package 300 according to this embodiment 3 may further include a fifth substrate 50 disposed below a second substrate 20. A second device 25 may be disposed on the fifth substrate 50. The fifth substrate 50 may further include fifth vias 51 penetrating it and connected to second vias 21 and each of the third vias 31 may have a greater diameter than each of the first vias 11. The fifth substrate 50 may be thinner than the second substrate 20. Except that first devices 15 are not mounted, the fifth substrate 50 m identical to the first substrate 10 described in the above embodiment 1.

Unlike the second substrate 20 according to the embodiment 1, the second substrate 20 according to this embodiment 3 may be horizontally connected to the second device 25 and may provide a first space S1 between the bottom surface of the first substrate 10 and the top surface of the fifth substrate 50. Besides that, the second substrate 20 may be identical to the second substrate 20 described in the above embodiment 1.

The stack module package 300 according to the embodiment 3 may further include a third substrate 30 interposed between the first substrate 10 and the second substrate 20 and having a greater thickness than the first substrate 10. Together with the second substrate 20, the third substrate 30 may provide the first space S1 between the bottom surface of the first substrate 10 and the top surface of the fifth substrate 50. Besides that, the third substrate 30 may be identical to the third substrate 30 described in the above embodiment 2.

As described above, the second device 25 may be horizontally connected to the second substrate 20 through the wire 3. Alternatively, although not shown in the drawing, the second device 25 may be vertically connected to the fifth substrate 50 through a solder ball (not shown). In more detail, a connection pad (not shown) and a solder ball (not shown) may be disposed on the bottom surface of the second device 25, and the second device 25 may be mounted on the fifth substrate 50. Therefore, the second device 25 may be electrically connected to the fifth signal patterns 52 and the fifth ground patterns 53 formed on the fifth substrate 50.

A connection relationship between the fifth substrate 50 and the second substrate 20 and a connection relationship between the third substrate 30 and the first substrate 10 may be identical to that between the second substrate 20 and the third substrate 30 described in the above embodiment 1. The other configurations are the same as previously described in the above embodiment 1

In providing a three-dimensionally arranged stack module package, vertical signal loss between substrates having different characteristics may be minimized Additionally, an advantageous structure may be provided in terms of heat. Furthermore, by using a substrate disposed inside the stack module package as a carrier substrate, the yield may be increased and processes may be simplified in manufacturing the stack module package.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A stack module package comprising:
a first substrate where a first device is mounted;
first vias penetrating the first substrate;
a second substrate where a second device is mounted, the second substrate having a greater thickness than the first substrate and the second device having a greater thickness than the first device;
second vias penetrating the second substrate,
a first signal pattern and a first ground pattern formed on the first substrate, each being connected to the first device; and
a second signal pattern and a second ground pattern formed on the second substrate, each being connected to at least one of the second vias and the second device,
wherein the first device and the second device are vertically connected to each other by at least one of the first vias and at least one of the second vias; and
the first signal pattern or the first ground pattern is connected to a plurality of the first vias.

2. The stack module package according to claim 1, further comprising connection parts connecting the first vias and the second vias, and each of the second vias has a greater diameter than each of the first vias.

3. The stack module package according to claim 1, wherein at least two first vias are connected to the first signal pattern in correspondence to one second via connected to the second signal pattern.

4. The stack module package according to claim 1, further comprising:
a third substrate interposed between the first substrate and the second substrate, the third substrate provided in a space between a bottom surface of the first substrate and a top surface of the second substrate; and
third vias penetrating the third substrate and connecting the first vias and the second vias,
wherein:
the second substrate has a greater thickness than the third substrate; and
each of the second vias has a greater diameter than each of the third vias.

5. The stack module package according to claim 1, wherein the first signal pattern is connected to a first bundle including a plurality of first vias;
the first ground pattern surrounds the first signal pattern to form a closed curve and is connected to a second bundle including a plurality of first vias; and
a protective layer is interposed between the first signal pattern and the first ground pattern.

6. The stack module package according to claim 1, wherein a high frequency signal or a high-speed electrical signal is delivered to the first signal pattern, the first ground pattern, the second signal pattern, and the second ground pattern.

7. The stack module package according to claim 1, wherein the second substrate comprises a cavity recessed toward a bottom thereof, and
wherein the second device is disposed in the cavity.

8. The stack module package according to claim 1, further comprising:
a third substrate interposed between the first substrate and the second substrate, the third substrate having a greater thickness than the first substrate, and the third substrate provided in a space between a bottom surface of the first substrate and a top surface of the second substrate; and
third vias penetrating the third substrate and connecting the first vias and the second vias,
wherein:
each of the third vias has a greater diameter than each of the firsts vias; and
a level of a top surface of the second device is disposed between a top surface and a bottom surface of the third substrate.

9. The stack module package according to claim 1, further comprising:
a fourth substrate disposed below the second substrate and horizontally connected to a third device; and
a thermal dissipation plate disposed below the fourth substrate and dissipating a heat generated from the third device.

10. The stack module package according to claim 9, wherein the third device consumes a higher power than the first device.

11. The stack module package according to claim 9, wherein the second substrate has a lower thermal conductivity than the first substrate.

12. The stack module package according to claim 1, further comprising:
a fifth substrate where the second device disposed on a top surface thereof and disposed below the second substrate; and
fifth vias penetrating the fifth substrate and connected to the second vias,
wherein:
the second substrate is horizontally connected to the second device and provides a space between a bottom surface of the first substrate and a top surface of the fifth substrate;
the second substrate has a greater thickness than the fifth substrate; and
each of the second vias has a greater diameter than each of the fifth vias.

13. The stack module package according to claim 12, further comprising a fifth signal pattern and a fifth ground pattern formed on the fifth substrate, each being connected to at least one of the fifth vias and connected to the second device,
wherein the fifth signal pattern is connected to a plurality of fifth vias.

14. A stack module package comprising:
a first substrate including first vias penetrating an inside thereof;
a first conductive pattern formed on the first substrate and connected to at least one of the first vias;
a second substrate including second vias penetrating an inside thereof; and
a second conductive pattern formed on the second substrate and connected to at least one of the second vias,
wherein the second substrate has a greater thickness than the first substrate;
the first conductive pattern and the second conductive pattern are vertically connected to each other by at least one of the first vias and at least one of the second vias; and
the first conductive pattern is connected to a plurality of first vias.

15. The stack module package according to claim 14, wherein each of the second vias has a greater diameter than each of the first vias.
